(19) United States
(12) Patent Application Publication
(10) Pub. No.: US 2024/0368374 A1
(43) Pub. Date: Nov. 7, 2024

(54) EPOXY RESIN COMPOSITION, LIQUID COMPRESSION MOLD MATERIAL, GLOB-TOP MATERIAL, AND SEMICONDUCTOR DEVICE

(71) Applicant: NAMICS CORPORATION, Niigata (JP)

(72) Inventors: Makoto SUZUKI, Niigata (JP); Yosuke SAKAI, Niigata (JP); Tsuyoshi KAMIMURA, Niigata (JP)

(21) Appl. No.: 18/291,751

(22) PCT Filed: Aug. 5, 2022
(86) PCT No.: PCT/JP2022/030151

§ 371 Date: Jan. 24, 2024

(30) Foreign Application Priority Data
Nov. 16, 2021 (JP) 2021-186626

(51) Int. Cl. C08K 3/28; C08G 59/14; C08G 59/22; C08G 59/24; C08G 59/50; C08G 59/62; C08K 3/36; H01L 23/29

(52) U.S. Cl. CPC C08K 3/28; C08G 59/1444; C08G 59/145; C08G 59/223; C08G 59/245; C08G 59/5073; C08G 59/621; C08K 3/36; H01L 23/29; C08K 2003/282; C08K 2201/005; C08K 2201/011

(57) ABSTRACT

[Problem to be solved] To provide an epoxy resin composition that is excellent in injectability and thermal conductivity of the cured product and can also be used for manufacturing a semiconductor device having high operation reliability. [Solution] An epoxy resin composition including an epoxy resin (A), a curing agent (B), a curing catalyst (C), and a filler (D), in which the filler (D) contains an aluminum nitride filler (D-1), the aluminum nitride filler (D-1) has an average particle size of 10.0 μm or less, the aluminum nitride filler (D-1) has a uranium content of 20 ppb or less, and a blending ratio of the aluminum nitride filler (D-1) to a total amount of the filler (D) is 70% by mass or more.

### TECHNICAL FIELD

The present invention relates to an epoxy resin composition, a liquid compression mold material, a glob top material, and a semiconductor device.

### BACKGROUND ART

Most of semiconductor elements such as integrated circuits constituting a semiconductor device are sealed with a sealing material. There are a plurality of molding methods for sealing semiconductor elements. Among these methods, compression molding, which is more suitable for manufacturing a relatively large molded article, is increasingly employed for sealing semiconductor elements. This is due to the spread of wafer-level chip size package technology (a technique involving directly sealing a wafer that is not cut into chips after the completion of circuit formation).

A known curable resin composition used for sealing semiconductor elements by compression molding is mainly a solid resin composition such as a granular resin composition. However, a liquid curable resin composition has been recently used in many cases, as a new compression molding technique is developed (hereinafter, such a liquid curable resin composition to be used for sealing by compression molding may be referred to as a “liquid compression mold material” or a “liquid compression molding (LCM) material”). As the liquid compression mold material, a liquid epoxy resin composition is often used from the viewpoint of the balance among various properties such as electrical properties, moisture resistance, heat resistance, mechanical properties, and adhesiveness.

In addition, semiconductor devices have been further improved in performance year by year. For example, electronic devices such as smartphones and personal computers utilizing semiconductor devices have been significantly reduced in weight, thickness, length, and size, and improved in performance. Therefore, there is an increasing need to efficiently dissipate heat generated by semiconductor devices to the outside. As a method for improving the heat dissipation of semiconductor devices, a technique of adding various fillers having excellent thermal conductivity to an epoxy resin composition has been proposed (for example, Patent Literatures 1 to 5).

Furthermore, it is also important to suppress malfunction in a device including a semiconductor device susceptible to α rays. As a method for suppressing such malfunction, a technique of limiting the content of an α-ray generating element such as uranium contained in a filler to be added to an epoxy resin composition to a predetermined value or less has been proposed. Further, a technique of limiting the a dose in a cured product of an epoxy resin composition to a predetermined value or less has been also proposed (for example, Patent Literatures 5 to 10).

### CITATION LIST

### Patent Literature

Patent Literature 1: WO 2018/181737 A

Patent Literature 2: WO 2018/181600 A

Patent Literature 3: JP-A-2017-039802

Patent Literature 4: JP-A-2011-079973

Patent Literature 5: JP-A-2016-023219

Patent Literature 6: JP-A-2005-248087

Patent Literature 7: JP-A-2011-236118

Patent Literature 8: JP-A-2014-005359

Patent Literature 9: JP-A-2017-195319

Patent Literature 10: JP-A-2017-110146

### SUMMARY OF INVENTION

### Problems to be Solved by Invention

On the other hand, there has been recently a demand for an epoxy resin composition that has excellent thermal conductivity of the cured product, in addition to excellent injectability to a sealing site, which is a basic characteristic required for an epoxy resin composition, and that can also be used for manufacturing a semiconductor device having high operation reliability. However, these three characteristics cannot be achieved in a well-balanced manner by known techniques exemplified in Patent Literatures 1 to 10, and the like.

The present invention has been made in view of the above circumstances. That is, an object of the present invention is to provide an epoxy resin composition that is excellent in injectability and thermal conductivity of the cured product and can also be used for manufacturing a semiconductor device having high operation reliability, a liquid compression mold material and a glob top material each including the epoxy resin composition, and a semiconductor device manufactured with these materials.

### Solution to Problems

The above-described object is achieved by the following present invention. That is, an epoxy resin composition of the present invention is an epoxy resin composition that includes an epoxy resin (A), a curing agent (B), a curing catalyst (C), and a filler (D). This epoxy resin composition is characterized in that the filler (D) contains an aluminum nitride filler (D-1), and the blending ratio of the aluminum nitride filler (D-1) to the total amount of the filler (D) is 70% by mass or more. Here, the average particle size of the aluminum nitride filler (D-1) is 10.0 μm or less. The uranium content of the aluminum nitride filler (D-1) is 20 ppb or less.

In an embodiment of the epoxy resin composition of the present invention, the α dose of a cured product of the epoxy resin composition is preferably 0.100 count/cm²·h or less.

In another embodiment of the epoxy resin composition of the present invention, the α dose of a cured product of the epoxy resin composition is preferably 0.005 count/cm²·h or less.

In another embodiment of the epoxy resin composition of the present invention, a cured product of the epoxy resin composition preferably has a thermal conductivity of 1.5 W/m·K or more.

In another embodiment of the epoxy resin composition of the present invention, the viscosity at 25° C. is preferably 500.0 Pa·s or less.

In another embodiment of the epoxy resin composition of the present invention, the average particle size of the aluminum nitride filler (D-1) is preferably 7.5 μm or less.

In another embodiment of the epoxy resin composition of the present invention, the blending amount of the filler (D) is preferably 50.0 to 90.0 parts by mass with respect to 100 parts by mass of the total mass of the epoxy resin composition. In another embodiment of the epoxy resin composition of the present invention, the filler (D) preferably further contains a silica filler (D-2). Here, the silica filler (D-2) has an average particle size of 5 nm to 120 nm. The uranium content of the silica filler (D-2) is 20 ppb or less.

In another embodiment of the epoxy resin composition of the present invention, the total blending ratio of the aluminum nitride filler (D-1) and the silica filler (D-2) to the epoxy resin composition is preferably 60.0% by mass to 85.0% by mass.

In another embodiment of the epoxy resin composition of the present invention, the shape of the filler (D) is preferably an indefinite shape.

In another embodiment of the epoxy resin composition of the present invention, the curing agent (B) is preferably any one or more selected from the group consisting of a phenolic curing agent, an amine curing agent, and an acid anhydride curing agent.

In another embodiment of the epoxy resin composition of the present invention, it is preferable that the curing agent (B) contains at least the phenolic curing agent, and the content ratio of the phenolic curing agent to the epoxy resin composition is 1% by mass to 5% by mass.

A liquid compression mold material of the present invention includes the epoxy resin composition of the present invention.

A glob top material of the present invention includes the epoxy resin composition of the present invention.

A semiconductor device according to a first aspect of the present invention includes a sealing material made of a cured product of the liquid compression mold material of the present invention.

A semiconductor device according to a second aspect of the present invention includes a sealing material made of a cured product of the glob top material according to the present invention.

### Effects of Invention

According to the present invention, it is possible to provide an epoxy resin composition that is excellent in injectability and thermal conductivity of the cured product and can also be used for manufacturing a semiconductor device having high operation reliability. Further, according to the present invention, it is possible to provide a liquid compression mold material and a glob top material each including this epoxy resin. Furthermore, according to the present invention, it is possible to provide a semiconductor device manufactured with these materials.

### DESCRIPTION OF EMBODIMENTS

The epoxy resin composition of the present embodiment is a resin composition that includes an epoxy resin (A), a curing agent (B), a curing catalyst (C), and a filler (D). In the epoxy resin composition of the present embodiment, the filler (D) contains an aluminum nitride filler (D-1) having (i) an average particle size of 10.0 μm or less and (ii) a uranium content of 20 ppb or less, and the blending ratio of the aluminum nitride filler (D-1) to the total amount of the filler (D) is 70% by mass or more.

In the following description, the aluminum nitride filler satisfying the conditions (i) and (ii) may be simply abbreviated as the “aluminum nitride filler”. Aluminum nitride fillers that do not satisfy at least one of the conditions (i) and (ii) are referred to as “other aluminum nitride fillers.” Fillers made of materials other than aluminum nitride are referred to as “fillers made of other materials.” Fillers other than the aluminum nitride filler satisfying the conditions (i) and (ii), i.e. both the “other aluminum nitride fillers” and the “fillers made of other materials” are collectively referred to as “other fillers.”

In the epoxy resin composition of the present embodiment, an aluminum nitride filler used as the filler has high thermal conductivity. Therefore, a cured product of the epoxy resin composition (that is, a sealing material for sealing a semiconductor element in a semiconductor device) is excellent in thermal conductivity. Therefore, the semiconductor device is also excellent in heat dissipation. In addition, since the average particle size of the aluminum nitride filler is 10.0 μm or less, the epoxy resin composition is also excellent in injectability.

In the epoxy resin composition of the present embodiment, the content of uranium as a generation source of α rays with respect to the total amount of the aluminum nitride filler used as the filler is 20 ppb or less. In addition, among the components constituting the epoxy resin composition of the present embodiment, each component other than the filler usually cannot substantially contain impurities such as uranium which is a generation source of α rays. Here, in the epoxy resin composition of the present embodiment, the blending ratio of the aluminum nitride filler having a uranium content of 20 ppb or less to the total amount of the filler is 70% by mass or more. That is, most of the filler is the aluminum nitride filler having a small α dose. As a result, the α dose of a cured product of the epoxy resin composition of the present embodiment can also be significantly suppressed. Therefore, a semiconductor device produced with the epoxy resin composition of the present embodiment has high operation reliability.

For the reasons described above, the α dose of a cured product of the epoxy resin composition of the present embodiment can be extremely easily reduced to 0.100 count/cm²·h or less. The α dose of the cured product is preferably 0.020 count/cm²·h or less, more preferably 0.010 count/cm²·h or less, and further preferably 0.005 count/cm²·h or less. The closer to 0 count/cm²·h the α dose of the cured product, the better. However, it is difficult to completely remove, from the filler (D) blended to the epoxy resin composition, an α ray generation source such as uranium as an impurity. Therefore, the lower limit value of the α dose of the cured product is practically 0.001 count/cm²·h or more.

The blending ratio of the aluminum nitride filler having a uranium content of 20 ppb or less with respect to the total amount of the filler can be appropriately selected within the range of 70% by mass to 100% by mass. However, when the aluminum nitride filler having a uranium content of 20 ppb or less and other fillers are used in combination as the filler, a smaller uranium content of other fillers is better. Specifically, the uranium content of other fillers is preferably 100 ppb or less and more preferably 20 ppb or less.

Next, each component constituting the epoxy resin composition of the present embodiment will be described below.

### Epoxy Resin (A)

The epoxy resin used in the epoxy resin composition of the present embodiment is not particularly limited as long as it is an epoxy resin generally used for semiconductor sealing. The epoxy resin is particularly preferably a polyfunctional epoxy resin from the viewpoint of thermal cycle resistance, and the like. As the epoxy resin to be blended in the epoxy resin composition, only one epoxy resin may be used, or two or more epoxy resins may be used in combination. When one epoxy resin is used, an epoxy resin that is liquid at normal temperature is used. When two or more epoxy resins are mixed and used, each epoxy resin may be in a solid state at normal temperature as long as it is in a liquid state at normal temperature after mixed. A specific example of the epoxy resin is an aliphatic epoxy resin compound having at least one epoxy group in the molecule and having no aromatic ring in the molecule. Another specific example thereof is an aromatic epoxy resin compound having at least one epoxy group in the molecule and having an aromatic ring in the molecule. The epoxy resin is not particularly limited as long as it is an epoxy resin generally used for semiconductor sealing. The epoxy resin is not particularly limited as long as it is an epoxy resin generally used for semiconductor sealing.

Examples of the aliphatic epoxy resin compound include monofunctional aliphatic epoxy resin compounds having one epoxy group in the molecule, such as alkyl alcohol glycidyl ether [butyl glycidyl ether, 2-ethylhexyl glycidyl ether, and the like] and alkenyl alcohol glycidyl ether [vinyl glycidyl ether, allyl glycidyl ether, and the like]; bifunctional aliphatic epoxy resin compounds having two epoxy groups in the molecule, such as alkylene glycol diglycidyl ether, poly(alkyleneglycol)diglycidyl ether, and alkenylene glycol diglycidyl ether; and polyfunctional aliphatic epoxy resin compounds having three or more epoxy groups in the molecule, such as polyglycidyl ethers of tri- or higher functional alcohols such as trimethylolpropane, pentaerythritol, and dipentaerythritol [trimethylolpropane triglycidyl ether, pentaerythritol (tri or tetra)glycidyl ether, dipentaerythritol(tri, tetra, penta or hexa)glycidyl ether, and the like].

More specific examples of the bifunctional aliphatic epoxy resin compounds include alkylene glycol diglycidyl ethers (alkanediol diglycidyl ethers) such as ethylene glycol diglycidyl ether, propylene glycol diglycidyl ether, 1,3-propanediol diglycidyl ether, 2-methyl-1,3-propanediol diglycidyl ether, 2-butyl-2-ethyl-1,3-propanediol diglycidyl ether, 1,4-butanediol diglycidyl ether (tetramethylene glycol diglycidyl ether), neopentyl glycol diglycidyl ether, 3-methyl-2,4-pentanediol diglycidyl ether, 2,4-pentanediol diglycidyl ether, 1,5-pentanediol diglycidyl ether (pentamethylene glycol diglycidyl ether), 3-methyl-1,5-pentanediol diglycidyl ether, 2-methyl-2,4-pentanediol diglycidyl ether, 2,4-diethyl-1,5-pentanediol diglycidyl ether, 1,6-hexanediol diglycidyl ether (hexamethylene glycol diglycidyl ether), 1,7-heptanediol diglycidyl ether, 3,5-heptanediol diglycidyl ether, 1,8-octanediol diglycidyl ether, 2-methyl-1,8-octanediol diglycidyl ether, and 1,9-nonanediol diglycidyl ether; and polyalkylene glycol diglycidyl ethers (including oligoalkylene glycol diglycidyl ethers) such as diethylene glycol diglycidyl ether, triethylene glycol diglycidyl ether, tetraethylene glycol diglycidyl ether, dipropylene glycol diglycidyl ether, polyethylene glycol diglycidyl ether, polypropylene glycol diglycidyl ether, poly (ethylene glycol/propylene glycol) diglycidyl ether, ditetramethylene glycol diglycidyl ether, tritetramethylene glycol diglycidyl ether,
polytetramethylene glycol diglycidyl ether, dipentamethylene glycol diglycidyl ether, tripentamethylene glycol diglycidyl ether, polypentamethylene glycol diglycidyl ether, dihexamethylene glycol diglycidyl ether, trihexamethylene glycol diglycidyl ether, and polyhexamethylene glycol diglycidyl ether.

Examples of the aromatic epoxy resin compound include glycidyl ethers of phenols such as bisphenol A, bisphenol F, bisphenol AD, bisphenol S, catechol, and resorcinol, glycidyl ether esters of hydroxycarboxylic acids such as p-hydroxybenzoic acid, monoglycidyl esters or polyglycidyl esters of carboxylic acids such as benzoic acid, phthalic acid, and terephthalic acid, glycidylamine-type epoxy compounds such as diglycidylaniline, diglycidyltoluidine, triglycidyl-p-aminophenol, and tetraglycidyl-m-xylylenediamine, and epoxy compounds having a naphthalene skeleton such as glycidyl esters of naphthol and glycidyl ether esters of ß-hydroxynaphthoic acid. Further, novolac compounds of phenols such as phenol, catechol, and resorcinol may be used. Among these, glycidylamine-type epoxy compounds are preferable.

### Curing Agent (B)

The curing agent used in the epoxy resin composition of the present embodiment is not particularly limited as long as it is a commonly used curing agent. Examples of the curing agent include an amine curing agent, an acid anhydride curing agent, and a phenolic curing agent. As the curing agent to be blended in the epoxy resin composition, only one curing agent may be used, or two or more curing agents may be used in combination. The blending amount of the curing agent is preferably such an amount that the stoichiometric equivalent ratio of the curing agent to the epoxy resin (curing agent equivalent/epoxy group equivalent) is 0.01 to 1.00. The equivalent ratio is more preferably 0.05 to 0.50. The equivalent ratio is further preferably 0.08 to 0.30. The blending ratio of the curing agent with respect to the liquid component obtained by removing the filler (solid component) from the epoxy resin composition is preferably 1% by mass to 100% by mass and more preferably 5% by mass to 15% by mass.

Specific examples of the amine curing agent include: aliphatic polyamines such as triethylene tetraamine, tetraethylene pentamine, m-xylene diamine, trimethyl hexamethylene diamine, and 2-methyl pentamethylene diamine; alicyclic polyamines such as isophorone diamine, 1,3-bisaminomethyl cyclohexane, bis (4-aminocyclohexyl) methane, norbornene diamine, and 1,2-diaminocyclohexane; piperazine polyamines such as N-aminoethyl piperazine and 1,4-bis (2-amino-2-methylpropyl) piperazine; and aromatic polyamines such as diethyl toluene diamine, dimethyl thiotoluene diamine, 4,4′-diamino-3,3′-diethyldiphenyl methane, bis (methylthio) toluene diamine, diaminodiphenyl methane, m-phenylene diamine, diaminodiphenyl sulfone, diethyltoluene amine, trimethylene bis (4-aminobenzoate), and polytetramethylene oxide-di-p-aminobenzoate. Examples of commercially available products include EPICURE-W and EPICURE-Z (Yuka-Shell Epoxy Co., Ltd., trade names), jER CURE (registered trademark)-W and jER CURE (registered trademark)-Z (Mitsubishi Chemical Corporation, trade names), KAYAHARD A-A, KAYAHARD A-B, and KAYAHARD A-S (Nippon Kayaku Co., Ltd., trade names), TOHTO AMINE HM-205 (Nippon Steel & Sumikin Chemical Co., Ltd., trade name), ADEKA HARDENER EH-101 (ADEKA Corporation, trade name), Epomic Q-640 and Epomic Q-643 (Mitsui Chemicals, Inc., trade names), DETDA80 (Lonza Co., trade name), and TOHTO AMINE HM-205 (Nippon Steel & Sumikin Chemical Co., Ltd., trade name).

Specific examples of the acid anhydride curing agent include alkylated tetrahydrophthalic anhydrides such as methyltetrahydrophthalic anhydride, methylhexahydrophthalic anhydride, and methyltetrahydrophthalic anhydride;

hexahydrophthalic anhydride; methylhymic anhydride; succinic anhydride substituted with an alkenyl group; methylnadic anhydride; and glutaric anhydride.

Specific examples of the phenolic curing agent include monomers, oligomers, and polymers having a phenolic hydroxyl group. Examples thereof include phenol novolac resin and an alkylated or allylated product thereof, cresol novolac resin, phenol aralkyl (containing a phenylene or biphenylene skeleton) resin, naphthol aralkyl resin, triphenol methane resin, and dicyclopentadiene-type phenol resin.

Among these, the phenolic curing agent is suitable. When at least the phenolic curing agent is used as the curing agent in the epoxy resin composition of the present embodiment, the content ratio of the phenolic curing agent to the epoxy resin composition is preferably 1% by mass to 5% by mass and more preferably 1.5% by mass to 4% by mass. When the content ratio of the phenolic curing agent is less than 1% by mass, adhesion between a semiconductor element or a substrate and the epoxy resin composition may be likely to lower. When the content ratio of the phenolic curing agent is more than 5% by mass, the viscosity of the epoxy resin composition increases, and thus the injectability may easily deteriorate.

### Curing Catalyst (C)

The curing catalyst used in the epoxy resin composition of the present embodiment is not particularly limited as long as it is a commonly used curing catalyst. Examples of the curing catalyst include a nitrogen-containing heterocyclic curing catalyst (including a type adducted or microencapsulated with epoxy resin or isocyanate resin) such as an imidazole compound, a tertiary amine curing catalyst, and a phosphorus compound curing catalyst. In particular, a nitrogen-containing heterocyclic curing catalyst is preferable from the viewpoint of thermal cycle resistance. As the curing catalyst to be blended in the epoxy resin composition, only one curing catalyst may be used, or two or more curing catalysts may be used in combination. There is no particular limitation. The blending amount of the curing catalyst with respect to 100 parts by mass of the epoxy resin composition is preferably 1% by mass to 15% by mass and more preferably 2% by mass to 10% by mass.

Specific examples of the nitrogen-containing heterocyclic curing catalyst include imidazole compounds such as 2-methylimidazole, 2-undecylimidazole, 2-heptadecylimidazole, 2-ethyl-4-methylimidazole, 2-phenylimidazole, 2-phenyl-4-methylimidazole, 2-phenyl-4,5-dihydroxymethylimidazole, 2-phenyl-4-methyl-5-hydroxymethylimidazole, 1-cyanoethyl-2-undecylimidazole, 1-cyanoethyl-2-ethyl-4-imidazole, 2-phenylimidazole, 1-benzyl-2-phenylimidazole, benzimidazole, 2,4-diamino-6-[2′-methylimidazolyl-(1′)]ethyl-s-triazine, 2-phenyl-4,5-dihydroxymethylimidazole, and 2,3-dihydro-1H-pyrrolo [1,2-a]benzimidazole. In this case, specific examples thereof include 2MZ, 2P4MZ, and 2E4MZ (all products manufactured by Shikoku Chemicals Corporation, trade names). Further, examples of the nitrogen-containing heterocyclic curing catalyst other than imidazole compounds include diazabicycloundecene (DBU), DBU-phenol salt, DBU-octanoic acid salt, DBU-p-toluenesulfonic acid salt, DBU-formic acid salt, DBU-orthophthalic acid salt, DBU-phenol novolac resin salt, DBU-based tetraphenylborate salt, diazabicyclononene (DBN), DBN-phenol novolac resin salt, diazabicyclooctane, pyrazole, oxazole, thiazole, imidazoline, pyrazine, morpholine, thiazine, indole, isoindole, purine, quinoline, isoquinoline, quinoxaline, cinnoline, and pteridine.

As the imidazole compound, encapsulated imidazole called microcapsule-type imidazole or epoxy-adduct-type imidazole can also be used. That is, an imidazole-based latent curing agent encapsulated by blocking, with an isocyanate compound, the surface of an imidazole compound adducted with urea or an isocyanate compound can be used. Alternatively, an imidazole-based latent curing agent encapsulated by blocking, with an isocyanate compound, the surface of an imidazole compound adducted with an epoxy compound can also be used. Specific examples thereof include Novacure HX3941HP, Novacure HXA3042HP, Novacure HXA3922HP, Novacure HXA3792, Novacure HX3748, Novacure HX3721, Novacure HX3722, Novacure HX3088, Novacure HX3741, Novacure HX3742, and Novacure HX3613 (all products manufactured by Asahi Kasei Chemicals Corporation, trade names), Amicure PN-23J and Amicure PN-40J (all products manufactured by Ajinomoto Fine-Techno Co.,Inc., trade names), and Fujicure FXR-1121 (manufactured by Fuji Kasei Co., Ltd., trade name).

### Filler (D)

As the filler used in the epoxy resin composition of the present embodiment, at least an aluminum nitride filler having (i) an average particle size of 10.0 μm or less and (ii) a uranium content of 20 ppb or less is used. As the filler, only the aluminum nitride filler satisfying the conditions (i) and (ii) may be used. However, if necessary, the aluminum nitride filler satisfying the conditions (i) and (ii) and other fillers may be used in combination.

When the aluminum nitride filler and other fillers (particularly, fillers made of other materials) are used in combination, the blending ratio of the aluminum nitride filler with respect to the total amount of the filler is preferably 70% by mass to 99.9% by mass and more preferably 80% by mass to 95% by mass, from the viewpoint of ensuring the thermal conductivity of the cured product. The content rate of the aluminum nitride filler in the epoxy resin composition of the present embodiment is preferably 50.0% by mass to 90% by mass, more preferably 52% by mass to 80% by mass, and further preferably 55% by mass to 70% by mass with respect to the total amount of the epoxy resin composition, from the viewpoints of reduction in hygroscopicity and linear expansion coefficients, improvement in strength, and solder heat resistance in addition to the thermal conductivity of the cured product.

Various fillers used in the epoxy resin composition are generally added for the purpose of improving the moisture resistance or thermal cycle resistance of a sealed site in a semiconductor device. On the other hand, the aluminum nitride filler satisfying the conditions (i) and (ii) which is used in the epoxy resin composition of the present embodiment has higher thermal conductivity than fillers made of materials (for example, alumina, silicon carbide, silicon nitride, and silica) for other fillers that are often used in general. Therefore, by using the aluminum nitride filler satisfying the conditions (i) and (ii) as the filler, excellent thermal conductivity of the cured product can also be realized. As a result, a semiconductor device manufactured using as a sealing material a cured product of the epoxy resin composition of the present embodiment improves heat dissipation of a sealed site and/or facilitates thermal design of a semiconductor device.

Further, the average particle size of the aluminum nitride filler used in the epoxy resin composition of the present embodiment is 10.0 μm or less. Therefore, the epoxy resin composition of the present embodiment is also excellent in injectability. Therefore, when a semiconductor device is manufactured with the epoxy resin composition of the present embodiment, the injectability for a site to be sealed is excellent. The average particle size of the aluminum nitride filler is preferably 7.5 μm or less and more preferably 6.0 μm or less. On the other hand, the lower limit value of the average particle size is not particularly limited. However, from the viewpoint of practical use such as availability of the aluminum nitride filler, the lower limit value of the average particle size is preferably 0.1 μm or more. The lower limit value of the average particle size is more preferably 0.5 μm or more. In the specification of the present application, the average particle size is calculated using a particle size distribution obtained by a volume average particle size (D50) particle size measurement method. More specifically, the particle size (volume average particle size (D50)) at which the cumulative volume of the remaining particles, obtained by sequentially subtracting the cumulative volume in a divided particle size range (channel) on the smaller particle size side from the particle size distribution, is 50% with respect to the cumulative volume of all particles is calculated. The average particle size is measured by a laser scattering diffraction method. Specifically, the average particle size is measured using a particle size distribution measuring apparatus (LS13320 manufactured by Beckman Coulter, Inc.) at flow rate: 50 ml/sec, measurement time: 90 sec, number of measurements: 1, particle condition: designated optical model, solvent: pure water, solvent refractive index: 1.333.

On the other hand, as the aluminum nitride filler, it is suitable to use a filler produced with metal aluminum or aluminum oxide as a raw material. Specifically, it is preferable to use an aluminum nitride filler produced by a direct nitriding method in which metal aluminum as a raw material is subjected to a nitriding reaction to produce aluminum nitride. Alternatively, it is also preferable to use an aluminum nitride filler produced by a reduction nitriding method in which carbon powder is added to aluminum oxide as a raw material, and then the aluminum oxide is subjected to a nitriding reaction to produce aluminum nitride. Here, the aluminum element constituting the aluminum nitride filler is derived from ore (bauxite) which contains uranium as a minor component. Therefore, aluminum nitride fillers produced by various production methods also contain uranium as inevitable impurities. Therefore, there is a possibility that a device including a semiconductor device malfunctions due to α rays emitted from uranium (the same applies to the alumina filler). Therefore, in the epoxy resin composition of the present embodiment, an aluminum nitride filler in which the uranium content is reduced to 20 ppb or less is used. Therefore, the reliability of the operation of the semiconductor device can be improved by reducing the α dose from a cured product (that is, a sealing material in the semiconductor device) obtained by curing the epoxy resin composition of the present embodiment.

Note that the uranium content in the aluminum nitride filler used in the epoxy resin composition of the present embodiment is more preferably 10 ppb or less and further preferably 7 ppb or less. The lower limit value of the uranium content is not particularly limited. The ideally most preferable lower limit value is 0 ppb. However, the practical lower limit value is preferably 0.5 ppb or more, and more preferably 0.8 ppb or more. When other fillers are used in addition to the aluminum nitride filler in the epoxy resin composition of the present embodiment, the uranium content of other fillers is also preferably 20 ppb or less, more preferably 10 ppb or less, and further preferably 7 ppb or less. The lower limit value of the uranium content of other fillers is not particularly limited. The ideally most preferable lower limit value is 0 ppb, but the practical lower limit value is preferably 0.5 ppb or more, and more preferably 0.8 ppb or more.

The uranium content in the filler is measured by an inductively coupled plasma mass spectrometry (ICP-MS) method. In the measurement, 1 g of filler powder to be measured is firstly weighed in a Teflon beaker. Next, an aqueous solution is prepared by adding 5 ml of nitric acid and 5 ml of hydrofluoric acid. Next, the concentrated solution obtained by heating the aqueous solution on a hot plate is placed in a measurement container. The measurement container is set to an inductively coupled plasma mass spectrometer. In this way, the uranium content is measured.

When fillers made of other materials are used in combination with the aluminum nitride filler in the epoxy resin composition of the present embodiment, one or more known fillers such as an alumina filler, a silicon carbide filler, a silicon nitride filler, and a silica filler can be used as other fillers. Among these, it is particularly suitable to use a silica filler (hereinafter, referred to as a “nano-sized silica filler” in some cases) having an average particle size of 5 nm to 120 nm and a uranium content of 20 ppb or less. By using such a nano-sized silica filler in combination, it is easy to reduce the hygroscopicity and the linear expansion coefficient and improve the strength and the solder heat resistance of the sealing material made of the cured product. Therefore, it is also easy to suppress the occurrence of peeling at the interface between a substrate and a cured product of the epoxy resin composition after a solder reflow treatment.

The nano-sized silica filler has a particle size smaller than that of the aluminum nitride filler. Therefore, it is easy to fill gaps between large-diameter aluminum nitride fillers with small-diameter nano-sized silica fillers. As a result, it is easy to further improve the filling rate of the filler in the epoxy resin composition. In addition, the thermal expansion coefficient of the nano-sized silica filler is very small compared to the thermal expansion coefficient of the aluminum nitride filler. Therefore, the thermal expansion coefficient of a cured product of the epoxy resin composition in which the aluminum nitride filler and the nano-sized silica filler are combined and blended as the filler can also be further reduced. As a result, it is easy to significantly improve the thermal cycle resistance of the cured product.

When the nano-sized silica filler is blended in the epoxy resin composition of the present embodiment, the blending ratio of the nano-sized silica filler with respect to the total amount of the epoxy resin composition is preferably 0.1% by mass to 25.0% by mass, more preferably 5.0% by mass to 25.0% by mass, and further preferably 10.0% by mass to 20.0% by mass, from the viewpoints of reduction in hygroscopicity and linear expansion coefficients and improvement in strength and solder heat resistance. By setting the blending ratio of the nano-sized silica filler to 0.1% by mass or more, it is easy to obtain the effects of reducing hygroscopicity and linear expansion coefficients and improving strength and solder heat resistance. By setting the blending ratio to 25.0% by mass or less, it is easy to suppress excessive thickening of the epoxy resin composition. Further, the particle size ratio (d2/d1) of the average particle size (d2) of the nano-sized silica filler to the average particle size (d1) of the aluminum nitride filler is preferably in the range of 1/200 to 1/5, more preferably in the range of 1/100 to 1/10, and further preferably in the range of 1/20 to 1/20. In particular, when the blending ratio of the nano-sized silica filler is increased, the excessive thickening of the epoxy resin composition can be easily suppressed by setting the particle size ratio (d2/dl) to 1/200 or more. Further, by setting the particle size ratio (d2/d1) to 1/5 or less, it is easy to fill gaps between large-diameter aluminum nitride fillers with small-diameter nano-sized silica fillers. Therefore, it is easy to improve the filling rate of the filler in the epoxy resin composition.

In the epoxy resin composition of the present embodiment, the total blending ratio of the aluminum nitride filler and the nano-sized silica filler with respect to the total amount of the epoxy resin composition is preferably in the range of 60.0% by mass to 85.0% by mass and more preferably in the range of 65.5% by mass to 80.5% by mass. By setting the total blending ratio to 65.5% by mass or more, it is easy to further improve the thermal conductivity of the cured product. Further, by setting the total blending ratio to 80.5% by mass or less, it is easy to suppress excessive thickening of the epoxy resin composition.

The thermal conductivity of the aluminum nitride filler blended in the epoxy resin composition of the present embodiment is not particularly limited. However, from the viewpoint of obtaining a cured product having high thermal conductivity, the thermal conductivity is preferably 145 W/m·K or more, and more preferably 230 W/m·K or more. The thermal conductivity of the nano-sized silica filler blended as necessary in the epoxy resin composition of the present embodiment is not particularly limited. However, from the same viewpoint as described above, it is preferably 1.2 W/m·K or more.

The shape of the filler used in the epoxy resin composition of the present embodiment is not particularly limited. The shape of the filler may be any of a spherical shape, an indefinite shape, a scaly shape, and the like. However, an indefinite shape is preferable from the viewpoint of improving the thermal conductivity of the cured product. An example of the indefinite-shape filler is a filler produced by a grinding method.

### (E) Other Components

In the epoxy resin composition of the present embodiment, other components other than the components (A) to (D) may be appropriately blended. The other components are not particularly limited. Examples of the other components include a coupling agent, an ion trapping agent, a leveling agent, an antioxidant, an antifoaming agent, a flame retardant, a colorant, a reactive diluent, and an elastomer. The blending amounts of the other blending agents are appropriately determined according to the purpose of use.

The epoxy resin composition of the present embodiment is prepared by mixing and stirring each component as a raw material. The mixing and stirring method is not particularly limited. A known mixing and stirring method can be used. For example, a roll mill can be used. When the epoxy resin (A) used as a raw material is solid, it is preferable to mix an epoxy resin liquefied by performing a heat treatment or the like before mixing with the other components. In the preparation of the epoxy resin composition, all components as raw materials may be mixed at a time. Alternatively, a primary mixture prepared by mixing some components selected from all the components as raw materials may be mixed with the remaining components. For example, when it is difficult to uniformly disperse the filler (D) in the epoxy resin (A), a primary mixture prepared by mixing the epoxy resin (A) and the filler (D) may be mixed with the remaining components.

The epoxy resin composition of the present embodiment is excellent in injectability. Therefore, it is easy to reduce the viscosity. Thus, it is easy to set the viscosity at 25° C. of the epoxy resin composition of the present embodiment to typically 500 Pa·s or less. The viscosity at 25° C. is preferably 400 Pa·s or less and more preferably 300 Pa·s or less. The lower limit value of the viscosity at 25° C. is not particularly limited. However, from the viewpoint of handling, the viscosity is preferably 10 Pa·s or more, more preferably 20 Pa·s or more, and further preferably 40 Pa·s or more. Note that the viscosity is measured at 25° C. and a rotation speed of 20 rpm using an HB-DV type viscometer manufactured by Brookfield Co. In the measurement, an SC4-14 spindle is used. The measurement range is 50 to 500 Pa·s.

The epoxy resin composition of the present embodiment can be widely applied to uses for resin sealing of various electronic components such as a semiconductor element and an LED package. When an electronic component is resin-sealed with the epoxy resin composition of the present embodiment, a known molding method can be used. Examples of the known molding method include (1) a molding method (so-called transfer molding) of filling a mold in which a member to be resin-sealed is previously disposed, with a liquid epoxy resin composition injected through a flow path (a gate, a runner, etc.) for resin supply communicating with a space in the mold and (2) a molding method (so-called compression molding) of previously filling a mold with a liquid epoxy resin composition and disposing a member to be resin-sealed and then performing press clamping. Compression molding does not require a flow path for resin supply. In this respect, compression molding has a feature that the use efficiency of the epoxy resin composition is nearly 100%. Therefore, compression molding has been widely used in recent years. The epoxy resin composition of the present embodiment can be suitably used as a member (liquid compression mold material) used for compression molding. Further, the epoxy resin composition of the present embodiment can be suitably used as a glob top material.

When resin sealing is performed with the epoxy resin composition of the present embodiment as a compression mold material, a glob top material, or the like, the epoxy resin composition of the present embodiment is suitably used for manufacturing a semiconductor device. In this case, the semiconductor device of the present embodiment includes a sealing material made of a cured product of the epoxy resin composition of the present embodiment. Then, at least a semiconductor element is resin-sealed by the sealing material.

### EXAMPLES

Hereinafter, the present invention will be described by way of Examples. However, the present invention is not limited only to the following Examples.

### 1. Preparation of Epoxy Resin Composition

Raw materials were mixed and stirred using a roll mill so as to have the blending ratios illustrated in Tables 1 to 4. Accordingly, epoxy resin compositions of Examples 1 to 16 and Comparative Examples 1 to 8 were prepared. The details of the components (A) to (D) used as raw materials are as follows.

### 2. Raw Material Components Used for Preparation of Epoxy Resin Composition

### Epoxy Resin (A)

Epoxy resin 1 (Epogose PT (general grade), diglycidyl ether of polytetramethylene glycol, epoxy equivalent: 440 g/eq, manufactured by Yokkaichi Chemical Company Limited)
Epoxy resin 2 (jER630, aminophenol-type liquid epoxy resin, epoxy equivalent: 98 g/eq, manufactured by Mitsubishi Chemical Corporation)
Epoxy resin 3 (HP4032D, naphthalene-type liquid epoxy resin, epoxy equivalent: 140 g/eq, manufactured by DIC Corporation)
Epoxy resin 4 (YDF8170, bisphenol F-type liquid epoxy resin, epoxy equivalent: 158 g/eq, manufactured by NIPPON STEEL Chemical & Material Co., Ltd.)
Epoxy resin 5 (RE410S, bisphenol A-type liquid epoxy resin, epoxy equivalent: 178 g/eq, manufactured by Nippon Kayaku Co., Ltd.)

### Curing Agent (B)

Curing agent 1 (MEH-8005, phenolic curing agent, hydroxyl equivalent: 139 to 143 g/eq, manufactured by Meiwa Plastic Industries, Ltd.)
Curing agent 2 (ETHACURE 100PLUS, amine-based curing agent, manufactured by Albemarle Corporation)
Curing agent 3 (HN-2200, acid anhydride curing agent, manufactured by Showa Denko Materials Co., Ltd.)

### Curing Catalyst (C)

Curing catalyst 1 (2P4MZ, 2-phenyl-4-methylimidazole, manufactured by Shikoku Chemicals Corporation)
Curing catalyst 2 (2MZA, 2,4-diamino-6-[2′-methylimidazolyl-(1′)]-ethyl-s-triazine, manufactured by Shikoku Chemicals Corporation)

### Filler (D)

### Aluminum Nitride Filler (D-1)

Filler AN1 (average particle size: 1.0 μm, uranium content: 1.0 ppb or less, grinding method)
Filler AN2 (average particle size 5.0 μm, uranium content: 5.0 ppb or less, thermal spraying method)

### Silica Filler (Silica Nanofiller) (D-2)

Filler S1 (YA050C-SM1, average particle size: 0.05 μm, manufactured by Admatechs Co., uranium content: 3.0 ppb or less, wet method)
Filler S2 (YA010C-SM1, average particle size: 0.01 μm, manufactured by Admatechs Co., uranium content: 3.0 ppb or less, wet method)
Filler S3 (YC100C-SM1, average particle size: 0.10 μm, manufactured by Admatechs Co., uranium content: 3.0 ppb or less, wet method)

### Other Fillers (Alumina Fillers) (D-3)

Filler A1 (A2-SX-G4, average particle size: 0.3 μm, manufactured by Admatechs Co., uranium content: 5.0 ppb or less, vaporized metal combustion (VMC) method)
Filler A2 (AZ10-75, average particle size: 10.5 μm, NIPPON STEEL Chemical & Material Co., Ltd., uranium content: 400 ppb, thermal spraying method)

### 3. Evaluation of Various Physical Property Values and Characteristic Values

The viscosity and injectability of the epoxy resin composition of each of Examples and Comparative Examples and the thermal conductivity, α dose, and peeling test result of the cured product of the epoxy resin composition of each of Examples and Comparative Examples were measured or evaluated by the following procedures. Results are illustrated in Tables 1 to 4.

### (Viscosity)

The viscosity of the epoxy resin composition of each of Examples and Comparative Examples was measured using an HB-DV type viscometer (model number: HB-DV1) manufactured by Brookfield Co. under the conditions of a liquid temperature of 25° C. and 20 rpm immediately after the epoxy resin composition was prepared.

### (Injectability)

The injectability of the epoxy resin composition of each of Examples and Comparative Examples was evaluated by the following procedure. First, a 12 inch silicon wafer half-diced with a width of 25 μm and a depth of 300 μm was prepared. Next, the epoxy resin composition was applied onto the silicon wafer and then compression-molded and cured using a mold heated to 120° C. The silicon wafer after the molding and curing process was cut so as to allow observation of the half-diced portion. Then, the cross section thereof was observed through an optical microscope to evaluate whether the half-diced portion having a width of 25 μm and a depth of 300 um was filled with the cured product of the epoxy resin composition. The evaluation criteria for injectability illustrated in Tables 1 to 3 are as follows.
A: The half-diced portion has been completely filled with the cured product without unevenness of the filler.
B: The half-diced portion has not been completely filled with the cured product or even when the half-diced portion has been filled with the cured product, the filler is unevenly distributed in the cured product.

### (Thermal Conductivity)

The thermal conductivity of a cured product of the epoxy resin composition of each of Examples and Comparative Examples was measured by the following procedure. First, the epoxy resin composition was heated and cured at 150° C. for 60 minutes to obtain a cured product having a thickness of 0.7 mm. The cured product was cut into length: 10 mm×width: 10 mm to prepare a measurement sample. Next, the thermal conductivity of the measurement sample was measured using a thermal conductivity measuring apparatus (LFA447 NanoFlash, manufactured by NETZSCH Co.).

### (αDose)

The epoxy resin composition of each of Examples and Comparative Examples was cured using a compression molding machine at a mold temperature of 150° C., a molding pressure of 250 kN, and a curing time of 60 minutes to obtain a test piece (length: 140 mm×width: 120 mm×thickness: 0.2 mm) made of the cured product. Six test pieces obtained were arranged in the width direction to obtain a test sample (total surface area: 1008 cm²). Next, the αdose radiated from the test sample was measured at an applied voltage of 1.9 KV, a PR-10 gas (argon: methane=9:1) of 100 m/min, and an effective counting time of 88 hours using a low level α ray measuring apparatus (LACS-4000M manufactured by Sumitomo Chemical Industry Company Limited).

### (Peeling Test)

The peeling test was performed by the following procedure. First, the epoxy resin composition of each of Examples 1, 2, 10, and 17 was printed on the surface of an FR-4 substrate (length and width: 4 cm×4 cm, thickness: 0.75 mm) in a region of 3 cm×3 cm in length and width such that the coating film thickness was 1 mm. Thereafter, the epoxy resin composition was cured at 150° C. for 60 minutes. As a result, a cured product layer made of the cured product of the epoxy resin composition was formed on the FR-4 substrate. Next, the FR-4 substrate on which the cured product layer was formed was allowed to stand in a thermos-hygrostat bath for 192 hours under the conditions of a temperature of 30° C. and a humidity of 60%. Thereafter, the substrate was immediately passed through the inside of a solder reflow furnace heated to 260° C. three times. By performing the heat treatment in this manner, an evaluation sample was obtained. The peeling properties of the obtained evaluation sample were evaluated by observing with an ultrasonic flaw detector (SAT) whether peeling occurred at the interface between the FR-4 substrate and the cured product layer. The results are illustrated in Table 4. The evaluation criteria for the evaluation results illustrated in Table 4 are as follows.
A: No peeling occurred at the interface between the FR-4 substrate and the cured product layer.
B: Peeling occurred at the interface between the FR-4 substrate and the cured product layer.

TABLE 1

| | | | Average | | Uranium | Production | Name of | Example | Example | Example | Example |
|---|---|---|---|---|---|---|---|---|---|---|---|
| | | Type of material | particle size | | content | method | material | 1 | 2 | 3 | 4 |
| Composition | Epoxy | Glycidyl-ether- | | | | | Epoxy | 3.60 | 3.60 | 3.60 | 5.00 |
| (Parts by mass) | resin | type epoxy resin | | | | | resin 1 | | | | |
| | (A) | Aminophenol-type | | | | | Epoxy | 12.80 | 12.80 | 12.80 | 11.40 |
| | | epoxy resin | | | | | resin 2 | | | | |
| | | Naphthalene-type | | | | | Epoxy | | | | |
| | | epoxy resin | | | | | resin 3 | | | | |
| | | Bisphenol F-type | | | | | Epoxy | | | | |
| | | epoxy resin | | | | | resin 4 | | | | |
| | | Bisphenol A-type | | | | | Epoxy | 3.90 | 3.90 | 3.90 | 3.90 |
| | | epoxy resin | | | | | resin 5 | | | | |
| | Curing | Phenolic curing | | | | | Curing | 1.90 | 1.90 | 1.90 | 1.90 |
| | agent | agent | | | | | agent 1 | | | | |
| | (B) | Amine curing agent | | | | | Curing | | | | |
| | | | | | | | agent 2 | | | | |
| | | Acid anhydride | | | | | Curing | | | | |
| | | curing agent | | | | | agent 3 | | | | |
| | Curing | 2-Phenyl | | | | | Curing | | | | |
| | catalyst | 4-methylimidazole | | | | | catalyst 1 | | | | |
| | (C) | 2-Methylimidazole | | | | | Curing | 0.80 | 0.80 | 0.80 | 0.80 |
| | | | | | | | catalyst 2 | | | | |
| | Filler | Silica nanofiller | 0.05 | μm | 3 ppb | Wet method | Filler | 12.50 | | | 12.50 |
| | (D) | (D-2) | | | or less | | S1 | | | | |
| | | | 10 | nm | 3 ppb | Wet method | Filler | | 12.50 | | |
| | | | | | or less | | S2 | | | | |
| | | | 100 | nm | 3 ppb | Wet method | Filler | | | 12.50 | |
| | | | | | or less | | S3 | | | | |
| | | Aluminum nitride | 1.0 | μm | 1 ppb | Grinding | Filler | 64.50 | 64.50 | 64.50 | 64.50 |
| | | filler (D-1) | | | or less | method | AN1 | | | | |
| | | | 5.0 | μm | 5 ppb | Thermal | Filler | | | | |
| | | | | | or less | spraying | AN2 | | | | |
| | | | | | | method | | | | | |
| | | Alumina | 0.3 | μm | 5 ppb | VMC | Filler | | | | |
| | | filler (D-3) | | | or less | method | A1 | | | | |
| | | | 10.5 | μm | 400 ppb | Thermal | Filler | | | | |
| | | | | | | spraying | A2 | | | | |
| | | | | | | method | | | | | |

| | | | | | |
|---|---|---|---|---|---|
| | Total amount of all components | 100.00 | 100.00 | 100.00 | 100.00 |
| | Total amount of filler (D) | 77.00 | 77.00 | 77.00 | 77.00 |
| | Total amount of aluminum | 64.50 | 64.50 | 64.50 | 64.50 |
| | nitride filler (D-1) | | | | |
| Composition | D-1/D | 83.8 | 83.8 | 83.8 | 83.8 |
| (% by masss) | (D-1 + D-2)/all components | 77.0 | 77.0 | 77.0 | 77.0 |
| Comparison | Viscosity (Pa · s) | 320 | 460 | 350 | 270 |
| charac- | Injectability | A | A | A | A |
| teristics | Thermal conductivity (W/m · K) | 1.9 | 1.9 | 1.9 | 1.9 |
| | α Dose (count/cm² · h) | 0.005 | 0.005 | 0.005 | 0.005 |

| | | | Average | | Uranium | Production | Name of | Example | Example | Example | Example |
|---|---|---|---|---|---|---|---|---|---|---|---|
| | | Type of material | particle size | | content | method | material | 5 | 6 | 7 | 8 |
| Composition | Epoxy | Glycidyl-ether- | | | | | Epoxy | 5.00 | 5.00 | 5.00 | 3.10 |
| (Parts by mass) | resin | type epoxy resin | | | | | resin 1 | | | | |
| | (A) | Aminophenol-type | | | | | Epoxy | 10.60 | 11.00 | 11.40 | 10.80 |
| | | epoxy resin | | | | | resin 2 | | | | |
| | | Naphthalene-type | | | | | Epoxy | | | | |
| | | epoxy resin | | | | | resin 3 | | | | |
| | | Bisphenol F-type | | | | | Epoxy | | | | |
| | | epoxy resin | | | | | resin 4 | | | | |
| | | Bisphenol A-type | | | | | Epoxy | 3.90 | 3.90 | 3.90 | 3.30 |
| | | epoxy resin | | | | | resin 5 | | | | |
| | Curing | Phenolic curing | | | | | Curing | 2.70 | 1.90 | 1.90 | 1.60 |
| | agent | agent | | | | | agent 1 | | | | |
| | (B) | Amine curing agent | | | | | Curing | | | | |
| | | | | | | | agent 2 | | | | |
| | | Acid anhydride | | | | | Curing | | | | |
| | | curing agent | | | | | agent 3 | | | | |
| | Curing | 2-Phenyl | | | | | Curing | | | | |
| | catalyst | 4-methylimidazole | | | | | catalyst 1 | | | | |
| | (C) | 2-Methylimidazole | | | | | Curing | 0.80 | 1.20 | 0.80 | 0.70 |
| | | | | | | | catalyst 2 | | | | |
| | Filler | Silica nanofiller | 0.05 | μm | 3 ppb | Wet method | Filler | 12.50 | 12.50 | 17.50 | 12.50 |
| | (D) | (D-2) | | | or less | | S1 | | | | |
| | | | 10 | nm | 3 ppb | Wet method | Filler | | | | |
| | | | | | or less | | S2 | | | | |
| | | | 100 | nm | 3 ppb | Wet method | Filler | | | | |
| | | | | | or less | | S3 | | | | |
| | | Aluminum nitride | 1.0 | μm | 1 ppb | Grinding | Filler | 64.50 | 64.50 | 59.50 | 68.00 |
| | | filler (D-1) | | | or less | method | AN1 | | | | |
| | | | 5.0 | μm | 5 ppb | Thermal | Filler | | | | |
| | | | | | or less | spraying | AN2 | | | | |
| | | | | | | method | | | | | |
| | | Alumina | 0.3 | μm | 5 ppb | VMC | Filler | | | | |
| | | filler (D-3) | | | or less | method | A1 | | | | |
| | | | 10.5 | μm | 400 ppb | Thermal | Filler | | | | |
| | | | | | | spraying | A2 | | | | |
| | | | | | | method | | | | | |

| | | | | | |
|---|---|---|---|---|---|
| | Total amount of all components | 100.00 | 100.00 | 100.00 | 100.00 |
| | Total amount of filler (D) | 77.00 | 77.00 | 77.00 | 80.50 |
| | Total amount of aluminum nitride filler (D-1) | 64.50 | 64.50 | 59.50 | 68.00 |
| Composition | D-1/D | 83.8 | 83.8 | 77.3 | 84.5 |
| (% by masss) | (D-1 + D-2)/all components | 77.0 | 77.0 | 77.0 | 80.5 |
| Comparison | Viscosity (Pa · s) | 360 | 370 | 280 | 480 |
| charac- | Injectability | A | A | A | A |
| teristics | Thermal conductivity (W/m · K) | 1.9 | 1.9 | 1.7 | 2.1 |
| | α Dose (count/cm² · h) | 0.005 | 0.005 | 0.004 | 0.005 |

TABLE 2

| | | | Average | | Uranium | Production | Name of | Example | Example | Example | Example |
|---|---|---|---|---|---|---|---|---|---|---|---|
| | | Type of material | particle size | | content | method | material | 9 | 10 | 11 | 12 |
| Composition | Epoxy | Glycidyl-ether- | | | | | Epoxy | 5.80 | 3.60 | 3.60 | 3.60 |
| (Parts by mass) | resin | type epoxy resin | | | | | resin 1 | | | | |
| | (A) | Aminophenol-type | | | | | Epoxy | 18.20 | 12.80 | 11.80 | 11.80 |
| | | epoxy resin | | | | | resin 2 | | | | |
| | | Naphthalene-type | | | | | Epoxy | | | 1.00 | |
| | | epoxy resin | | | | | resin 3 | | | | |
| | | Bisphenol F-type | | | | | Epoxy | | | | 1.00 |
| | | epoxy resin | | | | | resin 4 | | | | |
| | | Bisphenol A-type | | | | | Epoxy | 6.20 | 3.90 | 3.90 | 3.90 |
| | | epoxy resin | | | | | resin 5 | | | | |
| | Curing | Phenolic curing | | | | | Curing | 3.00 | 1.90 | 1.90 | 1.90 |
| | agent | agent | | | | | agent 1 | | | | |
| | (B) | Amine curing agent | | | | | Curing | | | | |
| | | | | | | | agent 2 | | | | |
| | | Acid anhydride | | | | | Curing | | | | |
| | | curing agent | | | | | agent 3 | | | | |
| | Curing | 2-Phenyl | | | | | Curing | | | | |
| | catalyst | 4-methylimidazole | | | | | catalyst 1 | | | | |
| | (C) | 2-Methylimidazole | | | | | Curing | 1.30 | 0.80 | 0.80 | 0.80 |
| | | | | | | | catalyst 2 | | | | |
| | Filler | Silica | 0.05 | μm | 3 ppb | Wet method | Filler | 0.00 | 12.50 | 12.50 | 12.50 |
| | (D) | nanofiller (D-2) | | | or less | | S1 | | | | |
| | | | 10 | nm | 3 ppb | Wet method | Filler | | | | |
| | | | | | or less | | S2 | | | | |
| | | | 100 | nm | 3 ppb | Wet method | Filler | | | | |
| | | | | | or less | | S3 | | | | |
| | | Aluminum nitride | 1.0 | μm | 1 ppb | Grinding | Filler | 65.50 | | 64.50 | 64.50 |
| | | filler (D-1) | | | or less | method | AN1 | | | | |
| | | | 5.0 | μm | 5 ppb | Thermal | Filler | | 64.50 | | |
| | | | | | or less | spraying | AN2 | | | | |
| | | | | | | method | | | | | |
| | | Alumina | 0.3 | μm | 5 ppb | VMC method | Filler | | | | |
| | | filler (D-3) | | | or less | | A1 | | | | |
| | | | 10.5 | μm | 400 ppb | Thermal | Filler | | | | |
| | | | | | | spraying | A2 | | | | |
| | | | | | | method | | | | | |
| | Total amount of all components | | | | | | | 100.00 | 100.00 | 100.00 | 100.00 |
| | Total amount of filler (D) | | | | | | | 65.50 | 77.00 | 77.00 | 77.00 |
| | Total amount of aluminum nitride filler (D-1) | | | | | | | 65.50 | 64.50 | 64.50 | 64.50 |
| Composition | D-1/D | | | | | | | 100.0 | 83.8 | 83.8 | 83.8 |
| (% by mass) | (D-1 + D-2)/all components | | | | | | | 65.5 | 77.0 | 77.0 | 77.0 |
| Comparison | Viscosity (Pa · s) | | | | | | | 240 | 200 | 350 | 340 |
| charac- | Injectability | | | | | | | A | A | A | A |
| teristics | Thermal conductivity (W/m · K) | | | | | | | 1.6 | 1.9 | 1.9 | 1.9 |
| | α Dose (count/cm² · h) | | | | | | | 0.005 | 0.005 | 0.005 | 0.005 |
| | | | Average | | Uranium | Production | Name of | Example | Example | Example | Example |
| | | Type of material | particle size | | content | method | material | 13 | 14 | 15 | 16 |
| Composition | Epoxy | Glycidyl-ether- | | | | | Epoxy | 3.60 | 3.60 | 3.60 | 3.60 |
| (Parts by mass) | resin | type epoxy resin | | | | | resin 1 | | | | |
| | (A) | Aminophenol-type | | | | | Epoxy | 12.80 | 12.80 | 12.80 | 12.50 |
| | | epoxy resin | | | | | resin 2 | | | | |
| | | Naphthalene-type | | | | | Epoxy | | | | |
| | | epoxy resin | | | | | resin 3 | | | | |
| | | Bisphenol F-type | | | | | Epoxy | | | | |
| | | epoxy resin | | | | | resin 4 | | | | |
| | | Bisphenol A-type | | | | | Epoxy | 3.90 | 3.90 | 3.90 | 3.90 |
| | | epoxy resin | | | | | resin 5 | | | | |
| | Curing | Phenolic curing | | | | | Curing | | | 1.90 | 1.90 |
| | agent | agent | | | | | agent 1 | | | | |
| | (B) | Amine curing agent | | | | | Curing | 1.90 | | | |
| | | | | | | | agent 2 | | | | |
| | | Acid anhydride | | | | | Curing | | 1.90 | | |
| | | curing agent | | | | | agent 3 | | | | |
| | Curing | 2-Phenyl | | | | | Curing | | | 0.80 | |
| | catalyst | 4-methylimidazole | | | | | catalyst 1 | | | | |
| | (C) | 2-Methylimidazole | | | | | Curing | 0.80 | 0.80 | | 0.80 |
| | | | | | | | catalyst 2 | | | | |
| | Filler | Silica | 0.05 | μm | 3 ppb | Wet method | Filler | 12.50 | 12.50 | 12.50 | 12.50 |
| | (D) | nanofiller (D-2) | | | or less | | S1 | | | | |
| | | | 10 | nm | 3 ppb | Wet method | Filler | | | | |
| | | | | | or less | | S2 | | | | |
| | | | 100 | nm | 3 ppb | Wet method | Filler | | | | |
| | | | | | or less | | S3 | | | | |
| | | Aluminum nitride | 1.0 | μm | 1 ppb | Grinding | Filler | 64.50 | 64.50 | 64.50 | 59.80 |
| | | filler (D-1) | | | or less | method | AN1 | | | | |
| | | | 5.0 | μm | 5 ppb | Thermal | Filler | | | | |
| | | | | | or less | spraying | AN2 | | | | |
| | | | | | | method | | | | | |
| | | Alumina | 0.3 | μm | 5 ppb | VMC method | Filler | | | | 5.00 |
| | | filler (D-3) | | | or less | | A1 | | | | |
| | | | 10.5 | μm | 400 ppb | Thermal | Filler | | | | |
| | | | | | | spraying | A2 | | | | |
| | | | | | | method | | | | | |

| | | | | | |
|---|---|---|---|---|---|
| | Total amount of all components | 100.00 | 100.00 | 100.00 | 100.00 |
| | Total amount of filler (D) | 77.00 | 77.00 | 77.00 | 77.30 |
| | Total amount of aluminum nitride filler (D-1) | 64.50 | 64.50 | 64.50 | 59.80 |
| Composition | D-1/D | 83.8 | 83.8 | 83.8 | 77.4 |
| (% by mass) | (D-1 + D-2)/all components | 77.0 | 77.0 | 77.0 | 72.3 |
| Comparison | Viscosity (Pa · s) | 300 | 280 | 360 | 380 |
| charac- | Injectability | A | A | A | A |
| teristics | Thermal conductivity (W/m · K) | 1.9 | 1.9 | 1.9 | 1.8 |
| | α Dose (count/cm² · h) | 0.005 | 0.005 | 0.005 | 0.005 |

TABLE 3

| | | | | | | | | Compar- | Compar- | Compar- | Compar- |
|---|---|---|---|---|---|---|---|---|---|---|---|
| | | | | | | | | ative | ative | ative | ative |
| | | | Average | | Uranium | Production | Name of | Example | Example | Example | Example |
| | | Type of material | particle size | | content | method | material | 1 | 2 | 3 | 4 |
| Composition | Epoxy | Glycidyl-ether- | | | | | Epoxy | 3.00 | 3.10 | | 8.00 |
| (Parts by mass) | resin | type epoxy resin | | | | | resin 1 | | | | |
| | (A) | Aminophenol-type | | | | | Epoxy | 9.00 | 1.70 | | |
| | | epoxy resin | | | | | resin 2 | | | | |
| | | Naphthalene-type | | | | | Epoxy | | | 2.50 | |
| | | epoxy resin | | | | | resin 3 | | | | |
| | | Bisphenol F-type | | | | | Epoxy | | | 7.00 | 2.50 |
| | | epoxy resin | | | | | resin 4 | | | | |
| | | Bisphenol A-type | | | | | Epoxy | | | | |
| | | epoxy resin | | | | | Resin 5 | | | | |
| | Curing | Phenolic curing | | | | | Curing | 4.90 | 2.60 | | 4.00 |
| | agent | agent | | | | | agent 1 | | | | |
| | (B) | Amine curing agent | | | | | Curing | | | 5.00 | |
| | | | | | | | agent 2 | | | | |
| | | Acid anhydride | | | | | Curing | | | | |
| | | curing agent | | | | | agent 3 | | | | |
| | Curing | 2-Phenyl | | | | | Curing | | | | |
| | catalyst | 4-methylimidazole | | | | | catalyst 1 | | | | |
| | (C) | 2-Methylimidazole | | | | | Curing | 0.10 | 0.20 | 0.50 | 0.50 |
| | | | | | | | catalyst 2 | | | | |
| | Filler | | 0.05 | μm | 3 ppb | Wet method | Filler | | | | |
| | (D) | | | | or less | | S1 | | | | |
| | | Silica | 10 | nm | 3 ppb | Wet method | Filler | | | | |
| | | nanofiller (D-2) | | | or less | | S2 | | | | |
| | | | 100 | nm | 3 ppb | Wet method | Filler | | | | |
| | | | | | or less | | S3 | | | | |
| | | Aluminum nitride | 1.0 | μm | 1 ppb | Grinding | Filler | 13.00 | | | |
| | | filler (D-1) | | | or less | method | AN1 | | | | |
| | | | 5.0 | μm | 5 ppb | Thermal | Filler | | | | |
| | | | | | or less | spraying | AN2 | | | | |
| | | | | | | method | | | | | |
| | | Alumina | 0.3 | μm | 5 ppb | VMC method | Filler | | 8.80 | | |
| | | filler (D-3) | | | or less | | A1 | | | | |
| | | | 10.5 | μm | 400 ppb | Thermal | Filler | 70.00 | 83.60 | 85.00 | 85.00 |
| | | | | | | spraying | A2 | | | | |
| | | | | | | method | | | | | |
| | Total amount of all components | | | | | | | 100.00 | 100.00 | 100.00 | 100.00 |
| | Total amount of filler (D) | | | | | | | 83.00 | 92.42 | 85.00 | 85.00 |
| | Total amount of aluminum nitride filler (D-1) | | | | | | | 13.00 | 0.00 | 0.00 | 0.00 |
| Composition | D-1/D | | | | | | | 15.7 | 0.0 | 0.0 | 0.0 |
| (% by mass) | (D-1 + D-2)/all components | | | | | | | 13.0 | 0.0 | 0.0 | 0.0 |
| Comparison | Viscosity (Pa · s) | | | | | | | 140 | 500< | 80 | 50 |
| charac- | Injectability | | | | | | | B | B | B | B |
| teristics | Thermal conductivity (W/m · K) | | | | | | | 2.1 | 2.8 | 2 | 2 |
| | α Dose (count/cm² · h) | | | | | | | 0.55 | 0.60 | 0.62 | 0.70 |
| | | | | | | | | Compar- | Compar- | Compar- | Compar- |
| | | | | | | | | ative | ative | ative | ative |
| | | | Average | | Uranium | Production | Name of | Example | Example | Example | Example |
| | | Type of material | particle size | | content | method | material | 5 | 6 | 7 | 8 |
| Composition | Epoxy | Glycidyl-ether- | | | | | Epoxy | 1.60 | 1.60 | 3.60 | 3.60 |
| (Parts by mass) | resin | type epoxy resin | | | | | resin 1 | | | | |
| | (A) | Aminophenol-type | | | | | Epoxy | | | 12.80 | 12.80 |
| | | epoxy resin | | | | | resin 2 | | | | |
| | | Naphthalene-type | | | | | Epoxy | | | | |
| | | epoxy resin | | | | | resin 3 | | | | |
| | | Bisphenol F-type | | | | | Epoxy | 2.60 | 2.60 | | |
| | | epoxy resin | | | | | resin 4 | | | | |
| | | Bisphenol A-type | | | | | Epoxy | | | 3.90 | 3.90 |
| | | epoxy resin | | | | | Resin 5 | | | | |
| | Curing | Phenolic curing | | | | | Curing | | | 1.90 | 1.90 |
| | agent | agent | | | | | agent 1 | | | | |
| | (B) | Amine curing agent | | | | | Curing | | | | |
| | | | | | | | agent 2 | | | | |
| | | Acid anhydride | | | | | Curing | 6.80 | 6.80 | | |
| | | curing agent | | | | | agent 3 | | | | |
| | Curing | 2-Phenyl | | | | | Curing | | | | |
| | catalyst | 4-methylimidazole | | | | | catalyst 1 | | | | |
| | (C) | 2-Methylimidazole | | | | | Curing | 0.80 | 0.80 | 0.80 | 0.80 |
| | | | | | | | catalyst 2 | | | | |
| | Filler | | 0.05 | μm | 3 ppb | Wet method | Filler | | 12.50 | 12.50 | 12.50 |
| | (D) | | | | or less | | S1 | | | | |
| | | Silica | 10 | nm | 3 ppb | Wet method | Filler | | | | |
| | | nanofiller (D-2) | | | or less | | S2 | | | | |
| | | | 100 | nm | 3 ppb | Wet method | Filler | | | | |
| | | | | | or less | | S3 | | | | |
| | | Aluminum nitride | 1.0 | μm | 1 ppb | Grinding | Filler | | | | |
| | | filler (D-1) | | | or less | method | AN1 | | | | |
| | | | 5.0 | μm | 5 ppb | Thermal | Filler | | | | |
| | | | | | or less | spraying | AN2 | | | | |
| | | | | | | method | | | | | |
| | | Alumina | 0.3 | μm | 5 ppb | VMC method | Filler | | | | 64.50 |
| | | filler (D-3) | | | or less | | A1 | | | | |
| | | | 10.5 | μm | 400 ppb | Thermal | Filler | 88.20 | 75.70 | 64.50 | |
| | | | | | | spraying | A2 | | | | |
| | | | | | | method | | | | | |

| | | | | | |
|---|---|---|---|---|---|
| | Total amount of all components | 100.00 | 100.00 | 100.00 | 100.00 |
| | Total amount of filler (D) | 88.20 | 88.20 | 77.00 | 77.00 |
| | Total amount of aluminum nitride filler (D-1) | 0.00 | 0.00 | 0.00 | 0.00 |
| Composition | D-1/D | 0.0 | 0.0 | 0.0 | 0.0 |
| (% by mass) | (D-1 + D-2)/all components | 0.0 | 12.5 | 12.5 | 12.5 |
| Comparison | Viscosity (Pa · s) | 120 | 80 | 30 | 450 |
| charac- | Injectability | B | B | B | A |
| teristics | Thermal conductivity (W/m · K) | 2.2 | 1.8 | 1.1 | 1.1 |
| | α Dose (count/cm² · h) | 0.80 | 0.68 | 0.37 | 0.005 |

TABLE 4

| | | | Average | | | | | | | | |
|---|---|---|---|---|---|---|---|---|---|---|---|
| | | | particle | | Uranium | Production | Name of | Example | Example | Example | Example |
| | | Type of material | size | | content | method | material | 1 | 2 | 10 | 17 |
| Composition | Epoxy | Glycidyl-ether-type | | | | | Epoxy | 3.60 | 3.60 | 3.60 | 3.60 |
| (Parts by | resin | epoxy resin | | | | | resin 1 | | | | |
| mass) | (A) | Aminophenol-type | | | | | Epoxy | 12.80 | 12.80 | 12.80 | 12.80 |
| | | epoxy resin | | | | | resin 2 | | | | |
| | | Naphthalene-type | | | | | Epoxy | | | | |
| | | epoxy resin | | | | | resin 3 | | | | |
| | | Bisphenol F-type | | | | | Epoxy | | | | |
| | | epoxy resin | | | | | resin 4 | | | | |
| | | Bisphenol A-type | | | | | Epoxy | 3.90 | 3.90 | 3.90 | 3.90 |
| | | epoxy resin | | | | | resin 5 | | | | |
| | Curing | Phenolic curing | | | | | Curing | 1.90 | 1.90 | 1.90 | 1.90 |
| | agent | agent | | | | | agent 1 | | | | |
| | (B) | Amine curing agent | | | | | Curing | | | | |
| | | | | | | | agent 2 | | | | |
| | | Acid anhydride | | | | | Curing | | | | |
| | | curing agent | | | | | agent 3 | | | | |
| | Curing | 2-Phenyl | | | | | Curing | | | | |
| | catalyst | 4-methylimidazole | | | | | catalyst 1 | | | | |
| | (C) | 2-Methylimidazole | | | | | Curing | 0.80 | 0.80 | 0.80 | 0.80 |
| | | | | | | | catalyst 2 | | | | |
| | Filler | Silica | 0.05 | μm | 3 ppb or less | Wet method | Filler | 12.50 | | 12.50 | |
| | (D) | nanofiller (D-2) | | | | | S1 | | | | |
| | | | 10 | nm | 3 ppb or less | Wet method | Filler | | 12.50 | | |
| | | | | | | | S2 | | | | |
| | | | 100 | nm | 3 ppb or less | Wet method | Filler | | | | |
| | | | | | | | S3 | | | | |
| | | Aluminum nitride | 1.0 | μm | 1 ppb or less | Grinding method | Filler | 64.50 | 64.50 | | 77.00 |
| | | filler (D-1) | | | | | AN1 | | | | |
| | | | 5.0 | μm | 5 ppb or less | Thermal spraying | Filler | | | 64.50 | |
| | | | | | | method | AN2 | | | | |
| | | Alumina filler (D-3) | 0.3 | μm | 5 ppb or less | VMC method | Filler | | | | |
| | | | | | | | A1 | | | | |
| | | | 10.5 | μm | 400 ppb | Thermal spraying | Filler | | | | |
| | | | | | | method | A2 | | | | |

| | | | | | |
|---|---|---|---|---|---|
| | Total amount of all components | 100.00 | 100.00 | 100.00 | 100.00 |
| | Total amount of filler (D) | 77.00 | 77.00 | 77.00 | 77.00 |
| | Total amount of aluminum nitride filler (D-1) | 64.50 | 64.50 | 64.50 | 77.00 |
| Composition | D-1/D | 83.8 | 83.8 | 83.8 | 100.0 |
| (% by mass) | (D-1 + D-2)/all components | 77.0 | 77.0 | 77.0 | 77.0 |

| | | | | |
|---|---|---|---|---|
| Peeling properties | A | A | A | B |

1. An epoxy resin composition comprising:
an epoxy resin (A);
a curing agent (B);
a curing catalyst (C); and
a filler (D), wherein
the filler (D) contains an aluminum nitride filler (D-1),
the aluminum nitride filler (D-1) has an average particle size of 10.0 μm or less,
the aluminum nitride filler (D-1) has a uranium content of 20 ppb or less, and
a blending ratio of the aluminum nitride filler (D-1) to a total amount of the filler (D) is 70% by mass or more.

2. The epoxy resin composition according to claim 1, wherein a cured product of the epoxy resin composition has an α dose of 0.100 count/cm²·h or less.

3. The epoxy resin composition according to claim 1, wherein the cured product of the epoxy resin composition has an α dose of 0.005 count/cm²·h or less.

4. The epoxy resin composition according to claim 1, wherein the cured product of the epoxy resin composition has a thermal conductivity of 1.5 W/m·K or more.

5. The epoxy resin composition according to claim 1, wherein the epoxy resin composition has a viscosity of 500.0 Pa·s or less at 25° C.

6. The epoxy resin composition according to claim 1, wherein the aluminum nitride filler (D-1) has an average particle size of 7.5 μm or less.

7. The epoxy resin composition according to claim 1, wherein a blending amount of the filler (D) is 50.0 to 90.0 parts by mass with respect to 100 parts by mass of a total mass of the epoxy resin composition.

8. The epoxy resin composition according to claim 1, wherein
the filler (D) further includes a silica filler (D-2),
the silica filler (D-2) has an average particle size of 5 nm to 120 nm, and
the silica filler (D-2) has a uranium content of 20 ppb or less.

9. The epoxy resin composition according to claim 8, wherein a total blending ratio of the aluminum nitride filler (D-1) and the silica filler (D-2) to the epoxy resin composition is 60.0% by mass to 85.0% by mass.

10. The epoxy resin composition according to claim 1, wherein the filler (D) has an indefinite shape.

11. The epoxy resin composition according to claim 1, wherein the curing agent (B) is any one or more selected from the group consisting of a phenolic curing agent, an amine curing agent, and an acid anhydride curing agent.

12. The epoxy resin composition according to claim 11, wherein the curing agent (B) contains at least the phenolic curing agent, and a content ratio of the phenolic curing agent to the resin composition is 1% by mass to 5% by mass.

13. A liquid compression mold material comprising the epoxy resin composition according to claim 1.

14. A glob top material comprising the epoxy resin composition according to claim 1.

15. A semiconductor device comprising a sealing material made of a cured product of the liquid compression mold material according to claim 13.

16. A semiconductor device comprising a sealing material made of a cured product of the glob top material according to claim 14.

17. A liquid compression mold material comprising the epoxy resin composition according to claim 2.

18. A glob top material comprising the epoxy resin composition according to claim 2.

19. A semiconductor device comprising a sealing material made of a cured product of the liquid compression mold material according to claim 17.

20. A semiconductor device comprising a sealing material made of a cured product of the glob top material according to claim 18.
